(19) United States
(12) Patent Application Publication
(10) Pub. No.: US 2024/0264633 A1
(43) Pub. Date: Aug. 8, 2024

(54) ELECTRONIC DISPLAY ASSEMBLY WITH A CHANNEL FOR AMBIENT AIR IN AN ACCESS PANEL

(71) Applicant: Manufacturing Resources International, Inc., Alpharetta, GA (US)

(72) Inventor: William Dunn, Alpharetta, GA (US)

(21) Appl. No.: 18/640,992

(22) Filed: Apr. 19, 2024

Related U.S. Application Data
(63) Continuation of application No. 17/961,346, filed on Oct. 6, 2022, now Pat. No. 11,989,059.
Application No. 17/961,346 is a continuation of application No. 17/000,425, filed on Aug. 24, 2020, now Pat. No. 11,507,141.
Application No. 17/000,425 is a continuation of application No. 16/373,810, filed on Apr. 3, 2019, now Pat. No. 10,795,413.

(51) Int. Cl. G06F 1/16; G02F 1/1333; G02F 1/1347; G09G 3/36; H05K 5/00

(52) U.S. Cl. CPC G06F 1/1637; G02F 1/133382; G02F 1/133385; G02F 1/1347; G09G 3/3648; H05K 5/0017

(57) ABSTRACT

An electronic display assembly includes a side assembly having a cover panel forming, at least in part, a front portion of said side assembly, and an electronic display located interior to said cover panel. An access panel is located rearward of the electronic display and includes an intake and a spaced apart exhaust. An airflow pathway for ambient air extends between the intake and the exhaust. The airflow pathway separates into at least a first and second sub-pathway at a first location fluidly adjacent to the intake. The first sub-pathway extends along a rear surface of the electronic display. The second sub-pathway extends along an interior surface of the access panel. At least the first and second sub-pathways rejoin at a second location fluidly adjacent to the exhaust.

### CROSS-REFERENCE TO RELATED APPLICATIONS

This application is a continuation of U.S. application Ser. No. 17/961,346 filed Oct. 6, 2022, which is a continuation of U.S. application Ser. No. 17/000,425 filed Aug. 24, 2020, which is a continuation of U.S. application Ser. No. 16/373,810 filed Apr. 3, 2019, the disclosures of each of which are hereby incorporated by reference as if fully restated herein.

### TECHNICAL FIELD

Exemplary embodiments relate generally to an electronic display assembly with a channel for ambient air in an access panel.

### BACKGROUND AND SUMMARY OF THE INVENTION

Electronic displays are increasingly being utilized in digital out of home (“DOOH”) applications. Such DOOH applications may include placement in indoor, semi-outdoor, and outdoor locations. These electronic displays are exposed to a number of potentially harmful environmental conditions including weather, solar loading, air contaminants, vandalism, wildlife, and the like. These electronic displays are sometimes placed in ruggedized enclosures to help protect the electronic displays and related components from such harmful environmental conditions. However, the electronic displays and related components typically generate heat which needs to be removed, along with heat experienced from the environmental conditions such as ambient temperatures, solar loading, and the like. Sometimes, the assembly will be designed to accept an open loop of ambient air which thermally interacts with a closed loop of circulating gas to remove the heat.

Access to the electronic display and related components is important in order to service the assemblies, make changes, and the like. In some installation locations, a rear surface of the assembly may receive particularly high levels of solar loading. This may be especially noticeable in applications where the assembly is tilted downward.

What is needed is an electronic display assembly with a channel for ambient air in an access panel. An electronic display assembly with a channel for ambient air in an access panel is provided.

An assembly for an electronic display may comprise a frame, a digital side assembly, and an access panel. A variety of peripheral devices, such as but not limited to, cameras, sensors, microphones, and the like may be located on the frame or throughout the assembly. The access panel may comprise an access panel open loop channel which is configured to receive ambient air. The digital side assembly may include one or more electronic displays, a digital side assembly open loop channel for ambient air, and a front channel for circulating gas located between a cover panel and a display layer. The space between the frame, the digital side assembly, and the access panel may define a cooling channel for the circulating gas. One or more electronic components for operating the electronic display, the peripheral devices, or other related equipment of the assembly may be located in the cooling channel. The front channel and the cooling channel may form a closed loop for the circulating gas. A heat exchanger may be located in the cooling channel which may form part of an open loop and the cooling loop.

The open loop may include the heat exchanger, the digital side assembly open loop, and the access panel open loop. The ambient air may be ingested by way of intakes located on the access panel. The ingested ambient air may be initially or subsequently separated into a number of flows. In exemplary embodiments, a different flow of ambient air may flow through each of the heat exchanger, the digital side assembly open loop, and the access panel open loop, and one or more fans may be dedicated to forcing air through one or more of these flow paths. One or more septa may be placed in the access panel for structural rigidity and to separate the second flow of ambient air. In other exemplary embodiments the access panel may be cooled by natural convection. The various ambient air flows may be separately exhausted from the assembly or may be merged before being exhausted.

The assembly may be configured for mounting to an external structure, such as but not limited to, a pole. The assembly may be mounted at a downward angle. The access panel may be mounted to the frame in a hinged manner. The digital side assembly may be mounted to the frame in a hinged manner.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical or equivalent features, and wherein:

FIG. 1 is a front perspective view of an exemplary assembly;

FIG. 2 is a front view of the assembly of FIG. 1 which also illustrates section line A-A and section line B-B;

FIG. 3 is a rear view of the assembly of FIG. 1;

FIG. 4A is a side view of the assembly of FIG. 1;

FIG. 4B is a side view of the assembly of FIG. 1 mounted to an external structure at a downward angle;

FIG. 5 is a side sectional view taken along section line A-A of FIG. 2;

FIG. 6 is a detailed side sectional view of FIG. 5;

FIG. 7 is a top sectional view taken along section line B-B of FIG. 2;

FIG. 8 is a detailed top sectional view of FIG. 7;

FIG. 9 is a rear view of the assembly of FIG. 3 with the rear cover removed to illustrate additional components of the assembly; and

FIG. 10 is a front view of another exemplary embodiment of the assembly, with certain components removed to illustrate multiple electronic displays.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

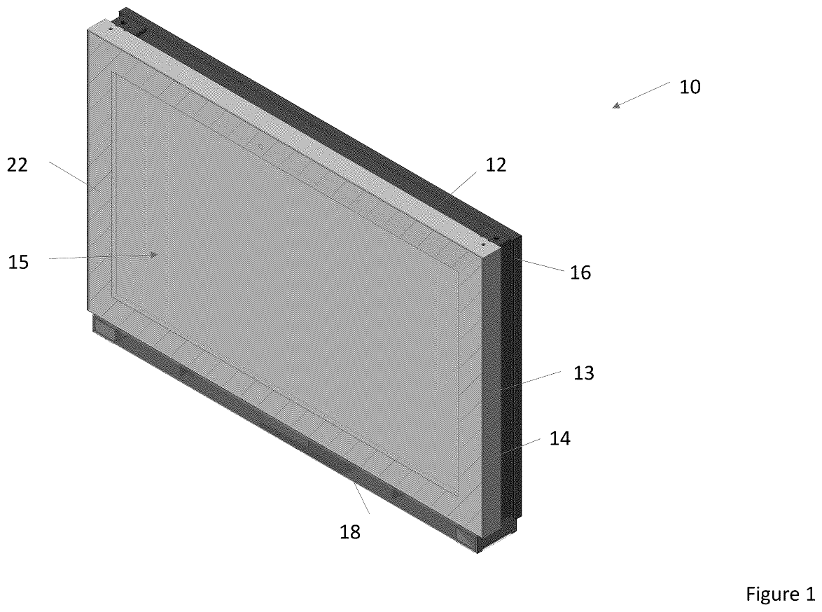

FIG. 1 is a front perspective view of an exemplary assembly 10. The assembly may comprise a frame 12. A digital side assembly 14 may be mounted to said frame 12. The digital side assembly 14 may comprise one or more electronic displays 15. The digital side assembly 14 may be mounted to said frame 12 in a hinged manner, such as but not limited to, along the upper edge of the frame 12 and the digital side assembly 14, though such is not required. A cover panel 22 may form a front surface of the digital side assembly 14.

An access panel 16 may be mounted to an opposing side of said frame 12 as compared to the digital side assembly 14. The access panel 16 may be mounted to said frame 12 in a hinged manner, such as but not limited to, along the upper edge of the frame 12 and the access panel 16, though such is not required. In exemplary embodiments, a lower portion 18 of the frame 12 may extend below the digital side assembly 14 and the access panel 16, though such is not required.

The access panel 16 may be comprised of sheet metal, black glass, or the like. In exemplary embodiments, the access panel 16 may be substantially comprised of a substantially opaque material. The access panel 16 may be a blank sheet. The access panel 16 may be moveably mounted to said frame 12 to permit access to various components of the assembly 10, including but not limited, to the frame 12, the digital side assembly 14, and any components located within the frame 12 or the digital side assembly 14.

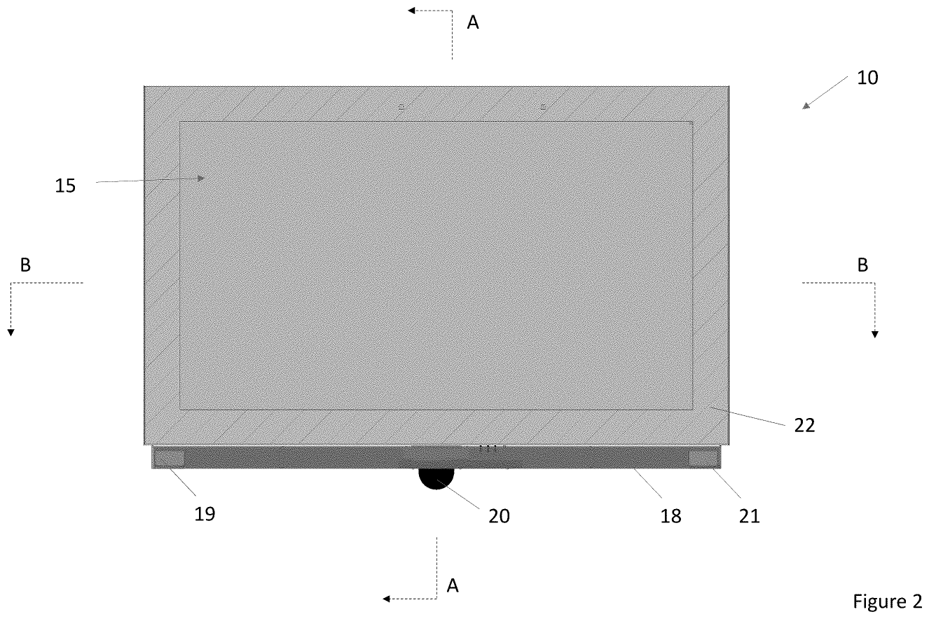

FIG. 2 is a front view of the assembly 10 which also illustrates section line A-A and section line B-B. One or more peripheral devices may be located on or within the assembly 10. In exemplary embodiments, such peripheral devices may be located along the lower portion 18, though any location is contemplated. Such peripheral devices may include, but are not limited to, a camera 20, a speaker 19, a sensor 21, a microphone, or the like. Any number and type of peripheral devices are contemplated and may be located at various locations throughout the assembly 10.

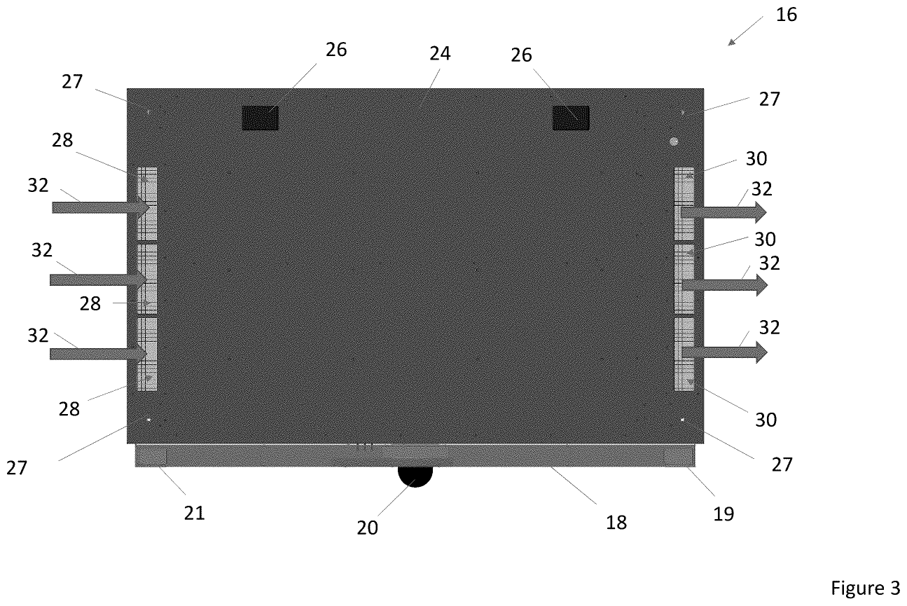

FIG. 3 is a rear view of the assembly 10. The access panel 16 may 16 may comprise a rear panel 24. An intake 28 may be located in the access panel 16. The intake 28 may be configured to facilitate the ingestion of ambient air 32. An exhaust 30 may be located in the access panel 16. The exhaust 30 may be configured to facilitate the exhaust of the ambient air 32. In exemplary embodiments, a number of intakes 28 may be located along one side of the rear panel 24, while a number of exhausts 30 may 30 may be located along an opposing side of the rear panel 24, though any number and location of intakes 28 and exhausts 30 is contemplated. In such exemplary embodiments, without limitation, each of the intakes 28 may be configured to ingest one or more flows of the ambient air 32 and each of the exhausts 30 may be configured to exhaust one or more flows of the ambient air 32. One or more antennas 26 may extend through apertures in the rear panel 24. A number of mounting apertures 27 may be located in the rear panel 24. In exemplary embodiments, the mounting apertures 27 may be configured to receive fasteners, brackets, clamps, pins, or the like which may connect to one or more internal components of the assembly 10.

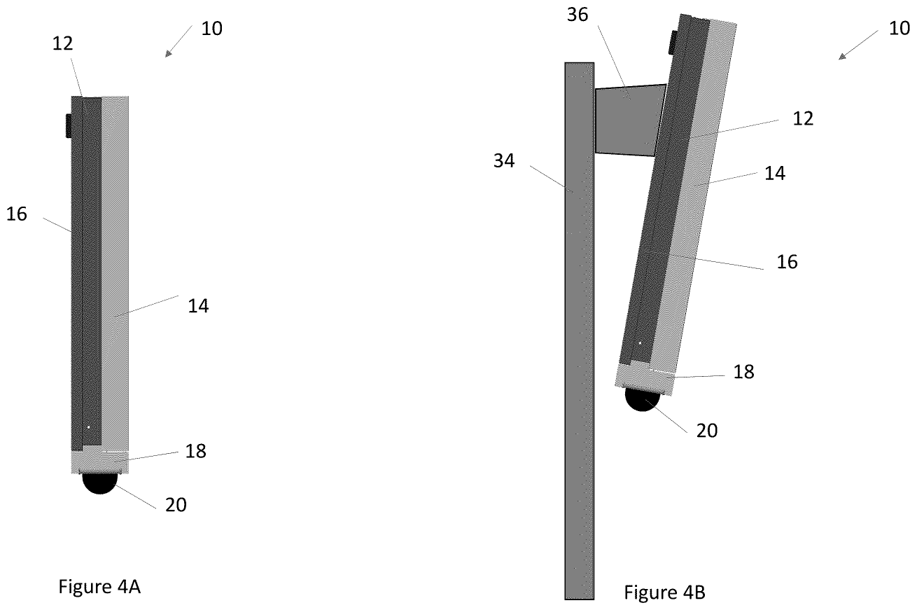

FIG. 4A is a side view of the assembly 10 and FIG. 4B is a side view of the assembly 10 mounted to an exemplary external structure 34 at a downward angle such as, but not limited to, 10 degrees. The mounting apertures 27 may be configured to receive fasteners, brackets, clamps, pins, or the like for mounting the assembly 10 to an external structure 34. In exemplary embodiments, the mounting apertures 27 may be circular and located near each corner of the rear panel, though any number, size, shape, and location of mounting apertures 27 are contemplated. The external structure 34 may be a pole, an elongate member, a wall, a surface, or the like. A mounting device 36 may be used to secure the assembly 10 to the external structure 34, though such is not required. In other exemplary embodiments, the assembly 10 may 10 may be mounted to the external structure 34 or the mounting device 36 directly. The antennae 26 may extend through the rear panel 24 to improve signal reception.

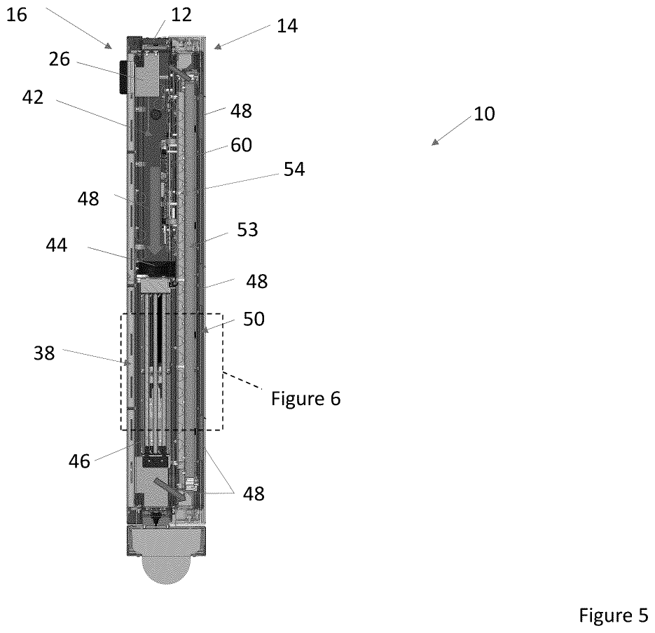

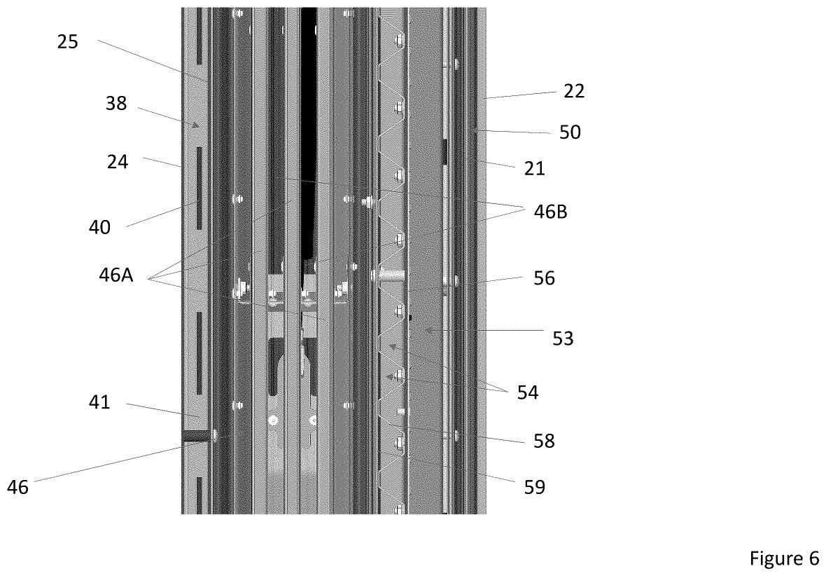

FIG. 5 is a side sectional view taken along section line A-A of FIG. 2 and FIG. 6 is a detailed side sectional view of FIG. 5. The mounting apertures 27 may permit the fasteners, brackets, clamps, pins, or the like to connect to the frame 12. The access panel 16 may comprise the rear panel 24 and an access panel interior panel 25, which may be located behind, spaced apart from, and substantially parallel to the rear panel 24. An access panel open loop channel 38 may be located between the rear panel 24 and the access panel interior panel 25. A number of stiffeners 41 may be located in the access panel open loop channel 38. Each of the stiffeners 41 may comprise one or more apertures 40 which permit the flow of the ambient air 32 therethrough. The stiffeners 41 may be spaced apart at regular or varying intervals. The apertures 40 may be spaced apart at regular or varying intervals to permit ambient air 32 to travel therethrough. The stiffeners 41 may be elongate members, though any size, shape, and number of stiffeners 41 are contemplated. A first flow 32A of the ambient air 32 may travel through the access panel open loop channel 38.

A cooling channel 42 may be located between the access panel 16 and the digital side assembly 14 and may be located within the frame 12. Various electronic components 60 for operating the electronic display 15 as well as peripheral devices and other components of the assembly 10, such as but not limited to, the camera 20, the speaker 19, the sensor 21, and the like may be located within the cooling channel 42. Such electronic components 60 may be mounted to the rear surface of the digital side assembly 14, the rear surface of the access panel 16, or the interior surfaces of the frame 12. The cooling channel 42 may be configured to receive circulating gas 48.

A heat exchanger 46 may be located within the cooling channel 42. The heat exchanger 46 may be configured to receive the ambient air 32 as well as the circulating gas 48. In exemplary embodiments, the heat exchanger 46 may comprise a number of closed loop layers 46B for the circulating gas 48 and a number of open loop layers 46A for the ambient air 32. The closed loop layers 46B may be alternated with the open loop layers 46A, though such is not required. The heat exchanger 46 may be a cross-flow, counter-flow, parallel flow, or other type of heat exchanger. The open loop layers 46A may be configured to receive a third flow 32C of the ambient air 32.

An electronic display layer 21 may be located behind the cover panel 22.

In exemplary embodiments, the display layer 21 is located behind, spaced apart from, and extends substantially parallel with the cover panel 22. The electronic display layer 21 may be, without limitation, comprised of liquid crystals. It is contemplated, however, that any type of electronic display 15 may be utilized within the digital side assembly 14 such as, but not limited to, an LCD, OLED, cathode ray tube, LED, or the like. Any number of films or additional layers are contemplated such as, but not limited to, enhancement films, diffusers, optical adhesives, polarizers, some combination thereof, or the like.

A front channel 50 may be located between the cover panel 22 and the electronic display layer 21. The front channel 50 may be configured to receive the circulating gas 48. The front channel 50 and the cooling channel 42 may form a closed loop. One or more closed loop fans 44 may be placed along the closed loop to force the circulating gas 48 through the closed loop. In exemplary embodiments the closed loop fans 44 may be located along an upper edge of the heat exchanger 46, though any location, or multiple locations, are contemplated. Additionally, while the circulating gas 48 is illustrating as flowing counterclockwise, it is contemplated that the circulating gas 48 may flow clockwise. Furthermore, while the circulating gas 48 is illustrated as flowing vertically through the cooling channel 42 and the front channel 50, it is contemplated that the circulating gas 48 may flow horizontally.

A rear digital side assembly layer 56 may be located behind the electronic display layer 21. In exemplary embodiments, the rear digital side assembly layer 56 is located behind, spaced apart from, and extends substantially parallel with the display layer 21. The rear digital side assembly layer 56 may comprise a number of illumination devices, such as but not limited to LEDs, mounted to a printed circuit board to form a backlight for the electronic display layer 21, though such is not required. The electronic display 15 may be directly backlit, edge lit, self-phosphorescing (e.g., OLED), or the like.

An interior digital side assembly panel 59 may be located behind the rear digital side assembly layer 56. In exemplary embodiments, the interior digital side assembly panel 59 is located behind, spaced apart from, and extends substantially parallel with the rear digital side assembly layer 56. A side assembly open loop channel 54 may be located between the rear digital side assembly layer 56 and the interior digital side assembly panel 59. The side assembly open loop channel 54 may be configured to receive a second flow 32B of the ambient air 32. A corrugated layer 58 may be provided in the side assembly open loop channel 54, though such is not required. The corrugated layer 58 may be provided in a honeycomb pattern, zig-zag pattern, as fins, as ribs, some combination thereof, or the like. In exemplary embodiments, the side assembly open loop channel 54 may be placed directly adjacent to the backlight 56. In this way, the second flow 32B of the ambient air 32 may remove heat generated by the backlight 56. The use of the corrugated layer 58 may improve the distribution of the second flow 32B of the ambient air 32 such that cooling is improved.

In exemplary embodiments, the cooling channel 42 may be located between the interior digital side assembly panel 59 and the access panel interior panel 25. A backlight cavity 53 may be located between the rear digital side assembly layer 56 and the electronic display layer 21. In exemplary embodiments, the backlight cavity 53 is partially or completely sealed. In other exemplary embodiments, a small flow of the circulating gas 48 may be directed to flow through the backlight cavity 53.

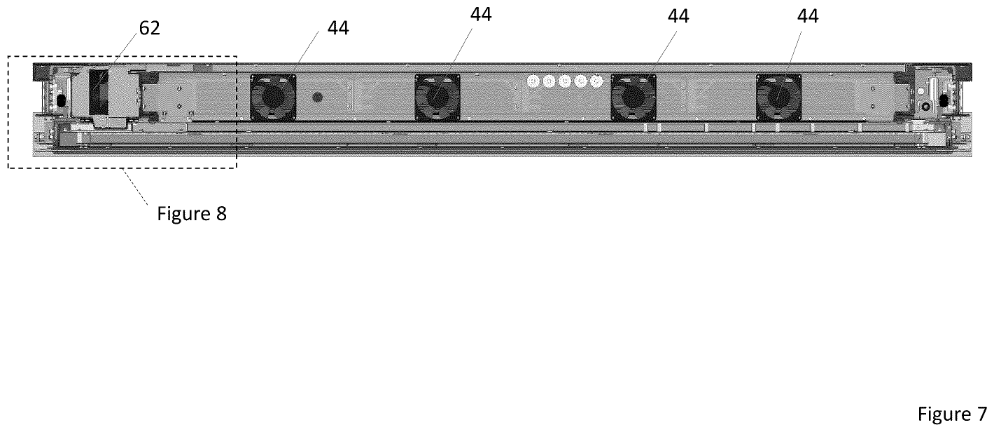

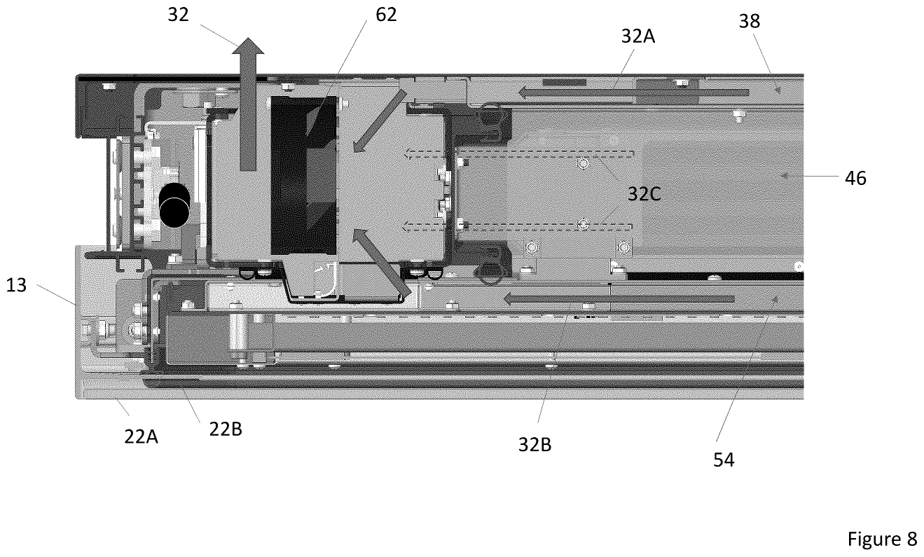

FIG. 7 is a top sectional view taken along section line B-B of FIG. 2 and FIG. 8 is a detailed top sectional view of FIG. 7. The closed loop fans 44 may be spaced apart at regular or irregular intervals along the heat exchanger 46. The first flow 32A of the ambient air 32 through the access panel open loop channel 38, the second flow 32B of the ambient air 32 through the side assembly open loop channel 54, as well as the third flow 32C of the ambient air 32 through the heat exchanger 46 may form an open loop. The various flows 32A-32C of the ambient air 32 though the various pathways may be caused by one or more open loop fans 62. The various flows 32A-32C of the ambient air 32 may be exhausted separately or may rejoined before being exhausted from the assembly 10. While the ambient air 32 is illustrated as flowing horizontally through the open loop, it is contemplated that the ambient air 32 may flow vertically through the open loop layer. While the ambient air 32 is illustrated as flowing from right to left in through the open loop layer, it is contemplated that the ambient air 32 may flow from left to right through the open loop layer.

The cover panel 22 may be comprised of multiple layers. For example, without limitation, the cover panel 22 may be comprised of a first 22A and a second 22B layer. The first and second layers 22A and 22B may be secured to one another by way of an optically clear adhesive. The cover panel 22 may be comprised or glass, a polymer, or the like. Any transparent or translucent material is contemplated.

The digital side assembly 14 may comprise a housing 13 for various components of the digital side assembly 14 such as, but not limited to, the cover panel 22, the electronic display layer 21, the rear digital side assembly layer 56, the side assembly open loop channel 54, and the interior digital side assembly panel 59, some combination thereof, or the like.

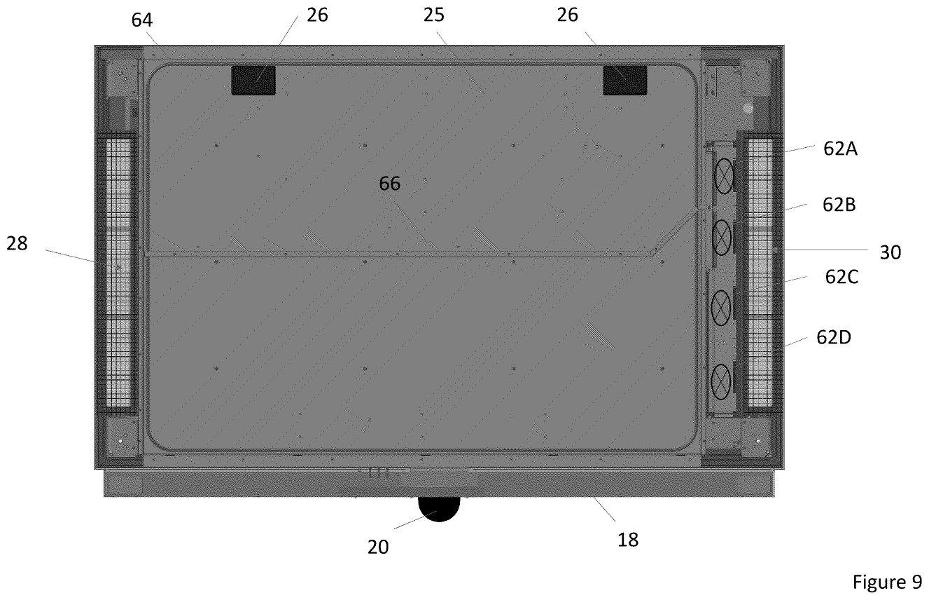

FIG. 9 is a rear view of the assembly 10 with the rear cover 24 removed such that the access panel interior panel 25 is shown. In exemplary embodiments, without limitation, each of the various flows 32A-32C may be ingested by various open loop fans 62A, 62B, 62C, and 62D. For example, without limitation, each of the open loop fans 62A, 62B, 62C, and 62D may be dedicated to ingesting ambient air 32 dedicated to a given open loop flow 32A-32C. As another example, without limitation, the first and second open loop fan 62A and 62B may ingest ambient air 32 directed to the first flow 32A for the access panel open loop channel 38 and the second flow 32B for the side assembly open loop channel 54. The third open loop fan 62C may ingest ambient air 32 directed to the third flow 32C for the heat exchanger 46. The fourth open loop fan 62D may ingest ambient air 32 directed to the fourth flow 32D for the heat exchanger 46 and the second flow 32B for the side assembly open loop channel 54. Any combination is contemplated. Various septa, dividers, channels, pathways, plenums, some combination thereof, or the like may be provided, positioned, and configured to direct the various flows into their respective pathways.

A gasket 64 may be located around a portion of the access panel interior panel 25 such that the access panel open loop channel 38 is sealed by compression of the rear panel 24 against the access panel interior panel 25.

One or more access panel septa 66 may be located within the access panel open loop channel 38. The access panel septa 66 may separate the first flow 32A traveling through the access panel open loop channel 38.

In other exemplary embodiments the access panel 16 may be cooled by convection. In such embodiments, the access panel open loop channel 38 may be provided but no open loop fans 62 may be required. Instead, the access panel open loop channel 38 may remain open to the ambient air 32, which may travel through the open loop by natural convection, wind, and the like. Alternatively, or in addition, the access panel open loop channel 38 may serve as a thermal buffer to the remainder of the assembly 10.

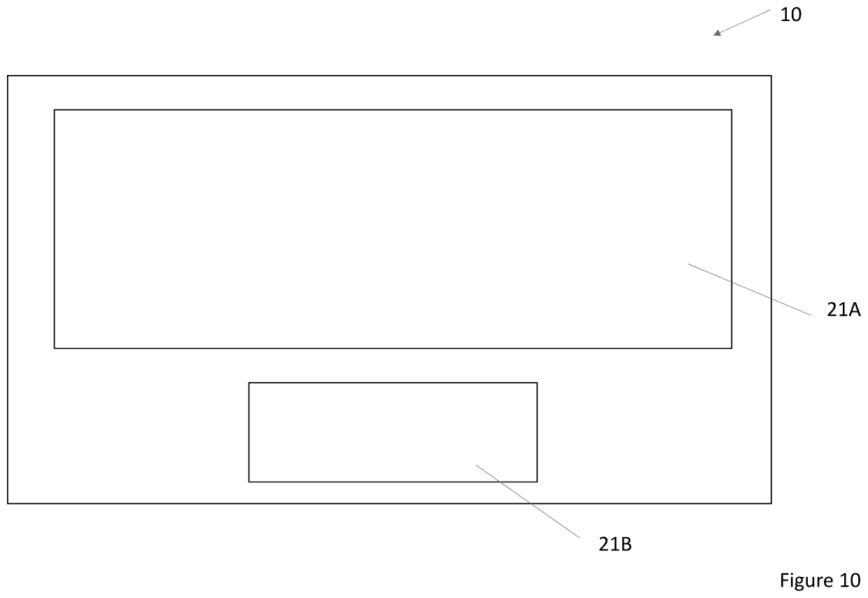

As illustrated in FIG. 10, in exemplary embodiments, without limitation, one or more electronic displays may be utilized. In such embodiments, multiple electronic display layers 21 may be provided to form multiple electronic display areas within the assembly 10. Such electronic display layers 21 may be separated from one another. For example, without limitation, a first electronic display layer 21A may be placed above a second electronic display layer 21B. As a further example, again without limitation, the first electronic display layer 21A may be placed on either side of the second electronic display layer 21B. As a further example, without limitation, the first and second electronic display layers 21A and 21B may be placed adjacent to one another to form the appearance of a larger display. Any number, positioning, orientation, size, shape, and the like of the electronic display layers 21 is contemplated. A common cover panel 22 may extend over all of the electronic display layers 21. In other exemplary embodiments, a separate cover panel 22 may extend over each electronic display layer 21.

It is notable that while the assembly 10 is illustrated in a landscape arrangement, it is contemplated that the assembly 10 may be provided in a portrait arrangement. Any size and shape assembly 10 is contemplated. In such embodiments, the lower portion 18 may be positioned such that it extends below the lower edge of the electronic display 15.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention. It is the intention, therefore, to limit the invention only as indicated by the scope of the claims.

What is claimed is:

1. An electronic display assembly comprising:
a side assembly comprising;
a cover panel forming, at least in part, a front portion of said side assembly; and
an electronic display located interior to said cover panel;
an access panel located rearward of the electronic display and comprising:
an intake; and
an exhaust spaced apart from the intake; and
an airflow pathway for ambient air extending between said intake and said exhaust, wherein said airflow pathway separates into at least a first sub-pathway and a second sub-pathway at a first location fluidly adjacent to said intake, said first sub-pathway extends along a rear surface of the electronic display, the second sub-pathway extends along an interior surface of the access panel, and at least said first sub-pathway and said second sub-pathway rejoin at a second location fluidly adjacent to said exhaust.

2. The electronic display assembly of claim 1 wherein:
the first sub-pathway and the second sub-pathway extend primarily in a same direction.

3. The electronic display assembly of claim 1 further comprising:
one or more fans located along the airflow pathway and configured to, when activated, move the ambient air through the airflow pathway.

4. The electronic display assembly of claim 3 wherein:
the one or more fans is located proximate to where the first sub-pathway and the second sub-pathway rejoin and interior to said exhaust.

5. The electronic display assembly of claim 1 further comprising:
a closed, continuous airflow pathway for circulating gas.

6. The electronic display assembly of claim 5 wherein:
the first sub-pathway extends interior to at least a portion of the closed, continuous airflow pathway.

7. The electronic display assembly of claim 6 wherein:
the closed, continuous airflow pathway extends forward and rearward of said electronic display.

8. The electronic display assembly of claim 5 further comprising:
one or more fans located along the closed, continuous airflow pathway for moving the circulating gas through the closed, continuous airflow pathway, when activated.

9. The electronic display assembly of claim 5 further comprising:
a heat exchanger located rearward of the electronic display, wherein a first portion of the heat exchanger defines, in part, the closed, continuous airflow pathway and a second portion of the heat exchanger defines, in part, the airflow pathway.

10. The electronic display assembly of claim 9 wherein:
the heat exchanger comprises ducted passageways, a first subset of multiple ones of which form part of the closed, continuous airflow pathway and a second subset of multiple ones of which form part of a third sub-pathway; and
said airflow pathway separates into said third sub-pathway at the first location and rejoins with said first sub-pathway and said second sub-pathway at said second location.

11. The electronic display assembly of claim 10 wherein:
the third sub-pathway extends rearward of the first sub-pathway and forward of the second sub-pathway.

12. The electronic display assembly of claim 11 wherein:
the first sub-pathway, the second sub-pathway, and the third sub-pathway each extend primarily in a same direction.

13. The electronic display assembly of claim 1 wherein:
the electronic display comprises a liquid crystal layer and a backlight; and
the first sub-pathway extends along the backlight.

14. The electronic display assembly of claim 1 further comprising:
a frame, wherein the side assembly and the access panel are mounted to opposing sides of the frame.

15. The electronic display assembly of claim 14 wherein:
each of said access panel and said side assembly are mounted to frame in a moveable manner.

16. The electronic display assembly of claim 14 further comprising:
a bracket for connecting the frame to a mounting structure, wherein said bracket is configured to orient a viewing side of said electronic display at a downward tilted angle when said frame is connected to said mounting structure.

17. The electronic display assembly of claim 16 wherein:
said mounting structure comprises a pole; and
said downward angle is between five and fifteen degrees.

18. The electronic display assembly of claim 1 wherein:
the access panel comprises a rear panel and an interior panel;
the rear panel forms, at least in part, a rear surface of said electronic display assembly;
the interior panel is located interior to said rear panel; and
the second sub-pathway extends between the rear panel and the interior panel.

19. An electronic display assembly comprising:
a side assembly comprising;
a cover panel forming, at least in part, a front portion of said side assembly; and
an electronic display located interior to said cover panel;
an access panel located rearward of the electronic display and comprising:
an intake; and
an exhaust spaced apart from the intake; and
an airflow pathway for ambient air extending between said intake and said exhaust, wherein said airflow pathway separates into at least a first sub-pathway and a second sub-pathway at a first location fluidly adjacent to said intake, said first sub-pathway extends along a rear surface of the electronic display, the second sub-pathway extends along an interior surface of the access panel, and at least said first sub-pathway and said second sub-pathway rejoin at a second location fluidly adjacent to said exhaust;
a closed, continuous airflow pathway for circulating gas extending, at least in part, rearward of the electronic display and the first sub-pathway; and
one or more fans, at least a first one of which is located along the airflow pathway and at least a second one of which is located along the closed, continuous airflow pathway.

20. An electronic display assembly comprising:
a side assembly comprising;
a housing;
a cover panel forming, at least in part, a front portion of said housing; and
an electronic display located interior to said cover panel, said electronic display comprising a liquid crystal layer and a backlight;
an access panel located rearward of the electronic display and comprising:
an intake;
an exhaust spaced apart from the intake;
a rear panel forming a rear surface of said electronic display assembly; and
an interior panel interior to said rear panel;
an airflow pathway for ambient air extending between said intake and said exhaust, wherein said airflow pathway separates into at least a first sub-pathway and a second sub-pathway at a first location fluidly adjacent to said intake, said first sub-pathway extends along a rear surface of the backlight, the second sub-pathway extends rearward of the first sub-pathway and between the interior panel and the rear panel of the access panel, and at least said first sub-pathway and said second sub-pathway rejoin at a second location fluidly adjacent to said exhaust;
a closed, continuous airflow pathway for circulating gas extending, at least in part, rearward of the electronic display and the first sub-pathway; and
one or more fans, at least a first one of which is located along the airflow pathway and at least a second one of which is located along the closed, continuous airflow pathway.
